(19) United States
(12) Patent Application Publication
(10) Pub. No.: US 2025/0370011 A1
(43) Pub. Date: Dec. 4, 2025

(54) DEVICE AND METHOD FOR CURRENT MEASUREMENT

(71) Applicant: Infineon Technologies AG, Neubiberg (DE)

(72) Inventors: Johannes GÜTTINGER, Lind ob Velden (AT); Tobias WERTH, Villach (AT); Benjamin KOLLMITZER, Pörtschach am Wörther See (AT); Gernot BINDER, Klagenfurt (AT); Diego LUNARDINI, Finkenstein am Faaker See (AT)

(21) Appl. No.: 19/216,130

(22) Filed: May 22, 2025

(30) Foreign Application Priority Data
Jun. 4, 2024 (DE) 102024115510.8

(51) Int. Cl. G01R 15/20

(52) U.S. Cl. CPC G01R 15/207

(57) ABSTRACT

A device for measuring current is proposed, including a current conductor having a first conductor section extending in one plane, and having a second conductor section adjoining end of the first conductor section and extending perpendicular to the plane, a differential magnetic field sensor arranged parallel to the plane, having a first sensor element and a second sensor element, wherein the first sensor element is at a first distance from the end of the first conductor section and the second sensor element is at a second distance from the end of the first conductor section.

### CROSS-REFERENCE TO RELATED APPLICATION

This application claims priority to Germany Patent Application No. 102024115510.8 filed on Jun. 4, 2024, the content of which is incorporated by reference herein in its entirety.

### TECHNICAL FIELD

The present disclosure generally relates to devices and methods for measuring current, in particular for stray-field-robust current measurement with regard to power switches.

### BACKGROUND

A power (semiconductor) switch is an electronic device used in power electronics to switch high electrical currents and voltages. Unlike mechanical power switches, power semiconductor switches are based on semiconductor technology and offer faster switching times and also greater efficiency and reliability.

Non-contact current measurement with magnetic sensors is attractive due to insulation between a power (semiconductor) circuit and a measuring circuit. By using a flux concentrator around a conductor, it is possible to detect a current-induced field using a single sensor element while simultaneously ensuring robustness against stray fields. However, measurement using an annular flux concentrator is cumbersome and requires a complex module and complex assembly, as the current-carrying wire must be enclosed by the annular flux concentrator. Such a sensor system cannot be integrated into a system in a housing or chip with a switching transistor.

For a robust measurement of a supply current without a flux concentrator, a differential concept is required that has lower sensitivity to common interference (e.g., external magnetic fields). With a bent conductor, the field generated is differential, but arrangement of the conductor can be difficult. With a bent conductor, the field generated is differential because the geometry of the conductor causes the magnetic fields generated at different points on the conductor to have different directions and intensities. This change in the direction and intensity of the magnetic field along the bent conductor results in different magnetic fields at different points on the conductor. In a differential concept, two sensor elements can be used that are positioned at different points on the bent conductor. These sensor elements detect the magnetic fields generated by the flow of current. Since the magnetic fields at these different points on the bent conductor are different, a differential signal is generated. This signal is the difference between the two detected magnetic fields. By using a differential concept, the sensor elements can detect the difference between the magnetic fields, which reduces sensitivity to common interference (e.g., stray fields) and can increase the accuracy of the current measurement.

With a straight planar conductor, the two sensor elements of a differential sensor cannot be placed at the maximum field because the maximum magnetic field occurs directly near the conductor. With a straight planar conductor, the magnetic field is symmetrically distributed around the conductor. This means that the magnetic field is strongest directly on the surface of the conductor and decreases with increasing distance. A differential sensor requires two sensor elements that are arranged at a certain distance from each other to measure the difference in magnetic field strengths. If the sensor elements are too close to the conductor and thus too close to each other, the difference in the magnetic field between the two points is small, which reduces the effectiveness of the differential measurement. To detect the maximum field, the sensor elements would have to be positioned very close to the surface of the conductor. However, it is difficult to place two sensor elements so close and at the same time symmetrically around the conductor without their affecting each other or without the physical space so allowing. In addition, practical aspects such as the physical size of the sensor elements and the need to mount them on a substrate can complicate placement at the optimum point. If the sensor elements are positioned further away from the conductor to achieve the difference necessary for differential measurement, the field strength decreases because the magnetic field weakens as the distance from the conductor increases. This results in a reduced sensitivity of the sensor, as the measurement of the magnetic field becomes less precise. In summary, this means that it is challenging to position the two sensor elements such that they detect the maximum magnetic field while simultaneously maintaining sufficient distance for effective differential measurement. This results in reduced sensitivity when measuring current using a straight planar conductor. There is therefore a need for improved concepts for stray-field-robust current measurement.

### SUMMARY

This need is addressed by devices and methods for (stray-field-robust) current measurement as claimed in the accompanying patent claims.

According to a first aspect of the present disclosure, a device for measuring current is proposed. The device includes a current conductor having a first conductor section extending in one plane. The current conductor also has a second conductor section adjoining one end of the first conductor section and extending perpendicular to the plane. The device includes a differential magnetic field sensor arranged parallel to the plane, having a first sensor element and a second sensor element. The first sensor element is at a first distance from the end of the first conductor section and the second sensor element is at a second distance from the end of the first conductor section.

The use of a differential magnetic field sensor having two sensor elements which are at different distances from the end of the first conductor section allows measurement of the difference between the two magnetic fields at the location of the sensor elements. This method is less susceptible to uniform external magnetic fields (stray fields), as such fields affect both sensor elements equally and thus disappear in the difference. The current conductor is configured so that the first section extends in one plane and the second section is perpendicular to the plane. This arrangement allows targeted detection of the magnetic field generated by the flow of current, and can minimize the influence of external magnetic fields or stray fields.

According to some implementations, the first sensor element is at the first distance in the direction of the first conductor section and the second sensor element is at the second distance in the direction of the first conductor section. Placement of the two sensor elements at different distances along the direction of the first conductor section allows the device to measure the difference in magnetic field strengths at these points. Stray fields that affect both sensor elements equally cancel each other out in the differential measurement, thereby minimizing the influence of external magnetic fields.

According to some implementations, the differential magnetic field sensor is arranged in the direction of the first conductor section after the end of the first conductor section. Placement of the sensor after the end of the first conductor section can help to reduce the impact of external magnetic fields generated along the conductor section on the measurement. This positioning can help to minimize stray fields caused, for example, by nearby power (semiconductor) switches.

According to some implementations, the first sensor element is at the first distance in the plane and perpendicular to the first conductor section and the second sensor element is at the second distance in the plane and perpendicular to the first conductor section. The two sensor elements of the differential magnetic field sensor are thus arranged in one plane and are located at a certain distance perpendicular to the first (and the second) conductor section.

According to some implementations, the differential magnetic field sensor is arranged outside of a corner or a bend between the first conductor section and the second conductor section of the current conductor. The first conductor section extends in one plane. The second conductor section extends perpendicular to the plane of the first section. The point at which the first and second conductor sections meet forms a corner or a bend. The differential magnetic field sensor is outside of this inflection (bend). That is to say, it is not within the inflection, but rather a little way outside, but still in a position where it can measure the magnetic field generated by the flow of current.

According to some implementations, the differential magnetic field sensor is configured to detect one or more magnetic field components parallel to the plane. The sensor can thus be aligned to measure magnetic field components that are in the same plane as the first conductor section or parallel thereto. This means, for example, that the sensor reacts sensitively to magnetic fields that extend horizontally or in the direction of the conductor surface, rather than perpendicular thereto.

According to some implementations, the differential magnetic field sensor includes at least one bridge circuit consisting of magnetoresistive elements or vertical Hall sensors. The first and second sensor elements are assigned to different bridge branches or bridge circuits. A bridge circuit is an electrical circuit that typically consists of four resistors (in this case, magnetoresistive elements or vertical Hall sensors) arranged in the form of a bridge. This arrangement can be used to measure small changes in resistance values or voltages very precisely. Magnetoresistive elements change their electrical resistance according to the strength and direction of the magnetic field that passes through them. Vertical Hall sensors measure the Hall voltage generated perpendicular to the flow of current in the sensor when a magnetic field acts parallel to the sensor element.

According to some implementations, the second conductor section of the current conductor extends within a semiconductor chip. This means that a portion of the current conductor is directly integrated in a semiconductor chip structure. The semiconductor chip can contain various electronic components and circuits.

According to some implementations, the semiconductor chip includes a vertical power MOSFET (Metal-Oxide-Semiconductor Field-Effect Transistor) which includes the second conductor section. This means that the second conductor section of the current conductor extends through the vertical MOSFET embedded within the semiconductor chip. This allows an integrated and stray-field-robust current measurement in power semiconductor switches to be achieved.

According to some implementations, the first conductor section extends toward a first terminal of a vertical power component and the second conductor section extends between the first terminal and a second terminal of the vertical power component. A vertical power component is a semiconductor device in which the current flows vertically through the structure, as opposed to a lateral device, in which the current flows horizontally. Typical examples are vertical power MOSFETs or IGBTs (Insulated Gate Bipolar Transistors). The first conductor section of the current conductor extends to the first terminal of the vertical power component, such as a vertical power MOSFET. The second conductor section extends between the first terminal and a second terminal of the same vertical power component. Placement of differential magnetic field sensors in close proximity to the vertical power component allows the sensors to detect the magnetic field (and thus the current) without distortion by external stray fields.

According to some implementations, the first terminal is arranged on a first surface of a semiconductor chip and the second terminal is arranged on an opposite second surface. This allows the current that is to be measured to flow vertically through the semiconductor chip from the first surface to the second surface.

According to another aspect of the present disclosure, a device for measuring current is proposed, including a substrate which spans a plane. The device also includes a current conductor having a first conductor section extending outside of the substrate and parallel to the plane. The current conductor has a second conductor section adjoining the first conductor section and extending within the substrate and perpendicular to the plane. The device also includes at least one magnetic field sensor arranged on the substrate to measure a magnetic field caused by a current through the second conductor section.

According to some implementations, the first conductor section extends toward the first terminal of a vertical power component and the second conductor section extends between the first terminal and a second terminal of the vertical power component. The vertical power component may be arranged within the substrate or on the substrate.

According to some implementations, the magnetic field sensor includes a differential magnetic field sensor having a first sensor element and a second sensor element on opposite sides of the second conductor section in the plane. The differential magnetic field sensor can thus include two sensor elements arranged on opposite sides of the second conductor section in the same plane. This arrangement allows the difference in the magnetic fields generated by the flow of current in the second conductor section to be measured on opposite sides.

According to some implementations, the second conductor section is surrounded by a flux concentrator arranged flat on the substrate and the at least one magnetic field sensor is arranged within at least one gap in the flux concentrator. A flux concentrator is a magnetic material used to amplify and focus the magnetic field generated by a current conductor. In this case, the flux concentrator is arranged flat on the substrate and surrounds the second conductor section. The flux concentrator amplifies the magnetic field generated by the flow of current in the second conductor section. This results in a higher field strength at the positions of the magnetic field sensors, thereby increasing the sensitivity and accuracy of the current measurement. The flux concentrator focuses the magnetic field and directs it specifically into the gaps in which the magnetic field sensors are placed. This minimizes the influence of stray fields and external magnetic interference, as the relevant magnetic field is concentrated and focused.

According to some implementations, the substrate includes a semiconductor chip having a vertical power component. The power component (e.g., MOSFET) may be connected to the substrate. The semiconductor chip may be insulated from the substrate.

According to some implementations, the semiconductor chip includes a vertical power MOSFET which forms the second conductor section.

According to some implementations, the at least one magnetic field sensor is configured to detect one or more magnetic field components parallel to the plane. For this purpose, the magnetic field sensor can be in the form of a magnetoresistive magnetic field sensor or in the form of a vertical Hall sensor.

### BRIEF DESCRIPTION OF THE FIGURES

Some examples of devices and/or methods are explained in more detail below merely by way of example with reference to the accompanying figures. In the figures:

FIG. 1A shows a device for measuring current according to an implementation of the present disclosure;

FIG. 1B shows a power semiconductor device having a differential magnetic field sensor;

FIG. 2A shows a device for measuring current according to another implementation of the present disclosure;

FIG. 2B shows a power semiconductor device having a differential magnetic field sensor;

FIG. 3A shows a first example of a differential magnetic field sensor;

FIG. 3B shows a second example of a differential magnetic field sensor;

FIG. 4A shows a device for measuring current according to another implementation of the present disclosure;

FIG. 4B shows a device for measuring current according to another implementation of the present disclosure;

FIG. 5A shows a device for measuring current according to another implementation of the present disclosure;

FIG. 5B shows a device for measuring current according to another implementation of the present disclosure;

FIG. 6A shows a device for measuring current according to another implementation of the present disclosure;

FIG. 6B shows a device for measuring current according to another implementation of the present disclosure; and

FIG. 7 shows a device for measuring current according to yet another implementation of the present disclosure.

### DETAILED DESCRIPTION

Some examples are now described in more detail with reference to the accompanying figures. However, further possible examples are not restricted to the features of these implementations that are described in detail. These may include modifications of the features, as well as equivalents and alternatives to the features. Furthermore, the terminology used herein to describe specific examples should not be restrictive for further possible examples.

The same or similar reference signs relate throughout the description of the figures to the same or similar elements or features, which may each be implemented identically or else in a modified form, while providing the same or a similar function. In the figures, the thicknesses of lines, layers and/or regions may also be exaggerated for clarification.

When two elements A and B are combined using an “or”, this should be understood as meaning that all possible combinations are disclosed, e.g., only A, only B, and also A and B, unless expressly defined otherwise in the individual case. “At least one of A and B” or “A and/or B” may be used as alternative wording for the same combinations. This applies equivalently to combinations of more than two elements.

If a singular form, e.g., “a, an” and “the”, is used, and the use of only a single element is neither explicitly nor implicitly defined as mandatory, other examples may also use multiple elements to implement the same function. When a function is described in the following as being implemented using multiple elements, further examples may implement the same function using a single element or a single processing entity. Furthermore, it goes without saying that the terms “comprises”, “comprising”, “has” and/or “having” when used describe the presence of the stated features, whole numbers, steps, operations, processes, elements, components and/or a group thereof, but do not thereby exclude the presence or the addition of one or more other features, whole numbers, steps, operations, processes, elements, components and/or a group thereof.

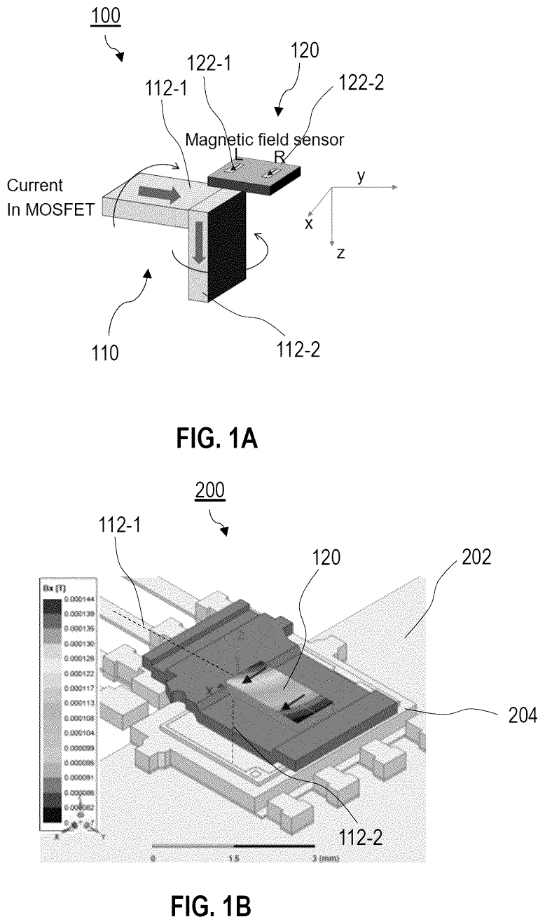

FIG. 1A schematically shows a device 100 for measuring current according to an implementation of the present disclosure.

The device 100 comprises a current conductor 110 having a first conductor section 112-1, extending in one plane (here: x-y plane). The current conductor 110 also has a second conductor section 112-2 adjoining one end of the first conductor section 112-1 and extending perpendicular to the plane (here: in the z direction). The two conductor sections 112-1, 112-2 are electrically conductively connected to each other and may be in one-piece form (e.g., in integral form) in some implementations. The two conductor sections 112-1, 112-2 form a bend in the current conductor 110 at the end of the first conductor section 112-1 and are thus essentially L-shaped. An electrical current to be measured can flow through the first conductor section 112-1 (here: in the x-y plane) and through the second conductor section 112-2 (here: in the z direction).

The device 100 additionally comprises a differential magnetic field sensor 120 arranged parallel to the plane (here: above the x-y plane), having a first sensor element 122-1 and at least a second sensor element 122-2. The first sensor element 122-1 is at a first distance d₁ from the end of the first conductor section 112-1 (e.g., from the bend) and the second sensor element 122-2 is at a second distance d₂>d₁ from the end of the first conductor section 112-1. In the implementation shown, the two distances are measured in the direction of the first conductor section 112-1.

According to some implementations, the differential magnetic field sensor 120 is configured to detect one or more magnetic field components parallel to the plane (here: x-y plane). Each of the sensor elements 122-1, 122-2 may thus be configured to detect magnetic field components in the x and/or y direction. These magnetic field components can be referred to as in-plane magnetic field components. The magnetic field measurement can be used to indirectly measure the electrical current through the current conductor 110.

The sensor elements 122-1, 122-2 can be in the form of xMR sensor elements or in the form of vertical Hall sensor elements. xMR sensors can detect magnetic field components which extend parallel to the sensor surface. They are sensitive to changes in magnetic field strength in the plane of the sensor element. For example, an AMR sensor situated in the x-y plane can detect magnetic field components along the x and y axes. xMR sensors change their electrical resistance according to the direction and strength of the magnetic field acting parallel to the sensor plane. This change is measured and used to determine the magnetic field strength. Vertical Hall sensor elements also allow measurement of a magnetic field in the plane. Vertical alignment of the Hall plates allows measurement of magnetic fields parallel to a housing and printed circuit board surface of the differential magnetic field sensor 120.

In some implementations, the first sensor element 122-1 may be arranged in a sensor plane (here: above the x-y plane) above the first conductor section 112-1 and within an extent of the first conductor section 112-1. This means that the first sensor element 122-1 of the differential magnetic field sensor 120 is located directly above the first conductor section 112-1 and is arranged within a projection of the first conductor section 112-1 onto the sensor plane above it (the plane of the magnetic field sensor 120). The first sensor element 122-1 can thus be spatially positioned over the first conductor section 112-1, e.g., vertically offset over the first conductor section 112-1, but still close to the generated magnetic field as a result of the flow of current in the first conductor section 112-1.

In some implementations, the second sensor element 122-2 may be arranged in the sensor plane above the first conductor section 112-1 and outside of an extent of the first conductor section 112-1. This means that the second sensor element 122-2 of the differential magnetic field sensor 120 is located spatially above the first conductor section 112-1, but is arranged outside of the projection of the first conductor section 112-1 onto the sensor plane above it (the plane of the magnetic field sensor 120).

In the example of FIG. 1A, the first conductor section 112-1 points, for example, in the y direction, the second conductor section 112-2 points in the z direction, and the sensor elements 122-1, 122-2 of the differential magnetic field sensor 120 are spaced in the y direction.

Placement of one sensor element within and one outside of the projection of the first conductor section 112-1 allows the differences in in-plane magnetic field strength at these two positions to be measured. This differential measurement can help to obtain accurate information about the magnetic field and thus the electrical current. Since both sensor elements 122-1, 122-2 experience the same external interference, the differential measurement cancels out this common interference. This can improve the robustness of the measurement against external magnetic fields and stray fields.

In other implementations, both the first sensor element 122-1 and the second sensor element 122-2 may be arranged in the sensor plane above the first conductor section 112-1 and outside of the extent of the first conductor section 112-1. This means that the first sensor element 122-1 and the second sensor element 122-2 of the differential magnetic field sensor 120 are located spatially above the first conductor section 112-1, but both are located outside of the projection of the first conductor section 112-1 onto the sensor plane above it (the plane of the magnetic field sensor 120). In this case, it can be assumed that d₂>d₁>0 (e.g., in the y direction).

FIG. 1B shows a perspective representation of a power semiconductor device 200 having a differential magnetic field sensor 120.

The power semiconductor device 200 is located on a substrate 202, for example a printed circuit board (PCB) or a leadframe. The power semiconductor device 200 has a housing 204, which can be in the form of a chip housing or package housing, for example. The power semiconductor device 200, for example comprising a vertical power transistor, also has three connection pins (e.g., source, drain, gate), one of which (e.g., a source pin) corresponds to the first conductor section 112-1 in the y direction. The second conductor section 112-2 extends perpendicular to the first conductor section 112-1 within the power semiconductor device 200 in the z direction. The second conductor section 112-2 can be formed by a source-drain channel of the vertical power transistor. The differential magnetic field sensor 120 is arranged on a surface of the housing 204, so that the first sensor element 122-1 is arranged in the sensor plane (here: above the housing 204) in the z direction above the first conductor section 112-1 and in the y direction within (or outside of) the extent of the first conductor section 112-1. The second sensor element 122-2 may be arranged in the sensor plane (here: above the housing 204) in the z direction above the first conductor section 112-1 (within the housing 204) and in the y direction outside of an extent of the first conductor section 112-1. The magnetic field strength of the magnetic field Bx is higher near the bend or inflection between the first conductor section 112-1 and the second conductor section 112-2 and decreases in the y direction with increasing distance from the bend. The differential magnetic field measurement can be used to infer the current through the power semiconductor device 200.

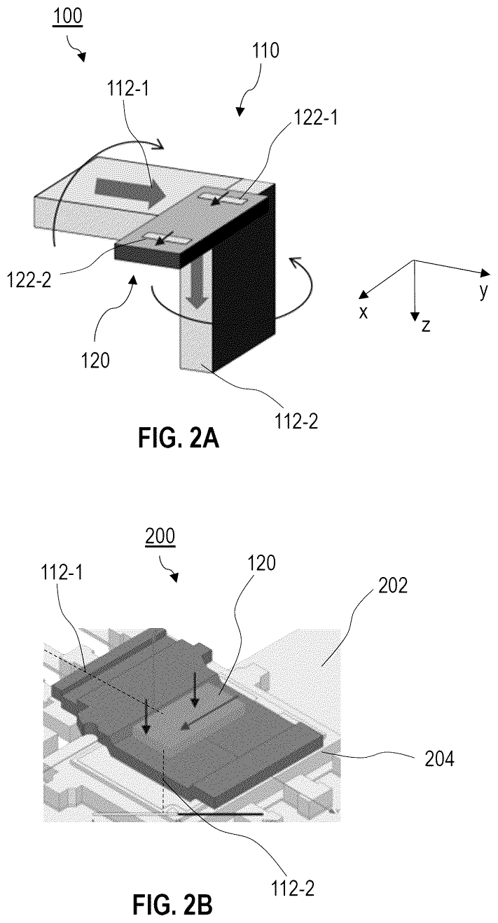

FIG. 2A schematically shows a device 100 for measuring current according to another implementation of the present disclosure.

In the case of the device 100 according to FIG. 2A, the differential magnetic field sensor 120 is rotated by 90° in the sensor plane above the x-y plane of the first conductor section 112-1 in comparison with FIG. 1A, but the sensitive direction of the sensors is retained (e.g., in the x direction). The first sensor element 122-1 is thus at the first distance d₁ in the plane and perpendicular to the first conductor section 112-1. The second sensor element 122-2 is at the second distance d₂ also in the plane and perpendicular to the first conductor section 112-1. The two sensor elements 122-1, 122-2 of the differential magnetic field sensor 120 are thus arranged in one sensor plane and are located at a certain distance perpendicular to the first conductor section 112-1 and the second conductor section 112-2. In the example shown, the first conductor section 112-1 points, for example, in the y direction, the second conductor section 112-2 points in the z direction, and the sensor elements 122-1, 122-2 of the differential magnetic field sensor 120 are spaced in the x direction.

In some implementations, the first sensor element 122-1 may be arranged in the sensor plane above the first conductor section 112-1 and within an extent of the first conductor section 112-1 (e.g., d₁=0). This means that the first sensor element 122-1 of the differential magnetic field sensor 120 is located directly above the first conductor section 112-1 and is arranged within the projection of the first conductor section 112-1 onto the plane above it (the plane of the magnetic field sensor 120). The first sensor element 122-1 can thus be spatially positioned over the first conductor section 112-1, e.g., vertically offset over the first conductor section 112-1, but still close to the generated magnetic field as a result of the flow of current in the first conductor section 112-1. In this case, it can be assumed that d₁=0 (in the x direction).

In some implementations, the second sensor element 122-2 may be arranged in the sensor plane above the first conductor section 112-1 and in the x direction outside of an extent of the first conductor section 112-1 (e.g., d₂>0). This means that the second sensor element 122-2 of the differential magnetic field sensor 120 is located spatially above the first conductor section 112-1, but is arranged in the x direction outside of the projection of the first conductor section 112-1 onto the plane above it (the plane of the magnetic field sensor 120). In this case, it can be assumed that d₂>0 (in the x direction).

In other implementations, both the first sensor element 122-1 and the second sensor element 122-2 may be arranged in the sensor plane above the first conductor section 112-1 and in the x direction outside of the extent of the first conductor section 112-1. This means that the first sensor element 122-1 and the second sensor element 122-2 of the differential magnetic field sensor 120 are located spatially above the first conductor section 112-1, but both in the x direction outside of the projection of the first conductor section 112-1 onto the sensor plane above it (the plane of the magnetic field sensor 120). In this case, it can be assumed that d₂>d₁>0 (in the x direction).

FIG. 2B shows a perspective representation of a power semiconductor device 200 having a differential magnetic field sensor 120. In comparison with the implementation of FIG. 1B, the differential magnetic field sensor 120 here is arranged with 90° rotation on the housing 204.

The power semiconductor device 200 is located on a substrate 202, for example a printed circuit board (PCB). The power semiconductor device 200 has a housing 204. The power semiconductor device 200, for example comprising a power transistor, also has three connection pins, one of which corresponds to the first conductor section 112-1 in the y direction. The second conductor section 112-2 extends perpendicular to the first conductor section 112-1 within the power semiconductor device 200 in the z direction. The differential magnetic field sensor 120 is arranged on the housing 204, so that the first sensor element 122-1 is arranged in the sensor plane (here: above the housing 204) in the z direction above the first conductor section 112-1 and in the x direction within (or outside of) the extent of the first conductor section 112-1. The second sensor element 122-2 may be arranged in the sensor plane (here: above the housing 204) in the z direction above the first conductor section 112-1 (within the housing 204) and in the x direction outside of an extent of the first conductor section 112-1. The magnetic field strength of the magnetic field Bx is higher near the bend between the first conductor section 112-1 and the second conductor section 112-2 and decreases in the y direction with increasing distance from the bend.

In each of the implementations shown in FIG. 1A-2B, the differential magnetic field sensor 120 is arranged outside of the corner or bend between the first conductor section 112-1 and the second conductor section 112-2 of the (L-shaped) current conductor 110. The first conductor section 112-1 extends in one plane (e.g., the x-y plane). The second conductor section 112-2 extends perpendicular to the plane of the first section 112-1. The point at which the first and second conductor sections 112-1, 112-2 meet forms a corner or bend. The differential magnetic field sensor 120 is located near but outside of this inflection (bend).

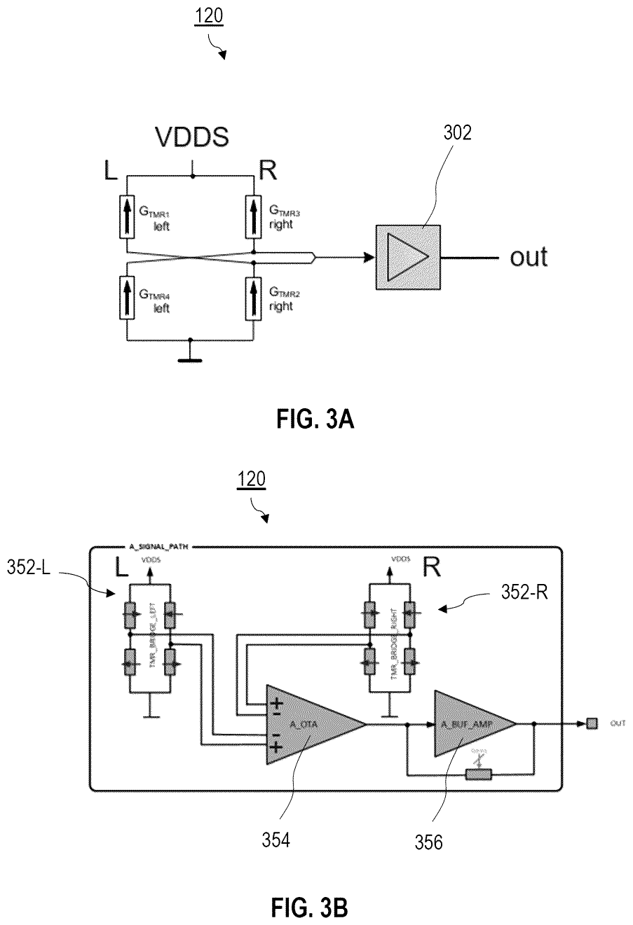

The differential magnetic field sensor 120 can comprise at least one bridge circuit consisting of magnetoresistive elements (xMR elements) or vertical Hall sensors. In this case, the first and second sensor elements 122-1, 122-2 may be assigned to different bridge branches or bridge circuits. An example of a differential magnetic field sensor 120 having a Wheatstone bridge circuit is shown in FIG. 3A.

FIG. 3A shows a circuit diagram of a Wheatstone bridge having magnetoresistive sensor elements (e.g., TMR sensor elements, TMR=Tunnel MagnetoResistance), which can be used for differential measurement of a magnetic field. The circuit diagram shows a Wheatstone bridge comprising four TMR sensor elements G_{TMR1left}, G_{TMR2right}, G_{TMR3right}, G_{TMR4left}. The sensor elements G_{TMR1left}, G_{TMR4left} are arranged on the left, and the sensor elements G_{TMR2right}, G_{TMR3right} are arranged on the right. The sensor elements G_{TMR1left} and G_{TMR2right} are connected in series between a supply terminal VDDS and ground. In parallel therewith, the sensor elements G_{TMR3right} and G_{TMR4left} are connected in series between the supply terminal VDDS and ground. The arrows on the sensor elements indicate the sensitivity directions (reference magnetizations) of the sensor elements, which means that they react to magnetic fields in these directions. A first output terminal is formed by a center tap between the sensor elements G_{TMR3right} and G_{TMR4left}. A second output terminal is formed by a center tap between the sensor elements G_{TMR1left} und G_{TMR2right}. The two output terminals of the Wheatstone bridge circuit are routed to a differential amplifier 302, which amplifies the differential signal and forwards it to an output (out).

Another example of a differential magnetic field sensor 120 having two Wheatstone bridge circuits is shown in FIG. 3B.

A first bridge 352-L consisting of TMR sensors on the left side is connected between VDDS (supply voltage) and ground. A second bridge 352-R consisting of TMR sensors on the right side is also connected between VDDS and ground. The first bridge 352-L forms the first sensor element 122-1, and the second bridge 352-R forms the second sensor element 122-2, or vice versa. An operational amplifier (operational transconductance amplifier, OTA) 354 has a first differential input for a first differential voltage from the first bridge 352-L. OTA 354 has a second differential input for a second differential voltage from the second bridge 352-R. A buffer amplifier 365 at the output of the OTA 354 amplifies and stabilizes the output signal of the OTA 354.

The following description discloses further alternative concepts for an integration of stray-field-robust current sensors.

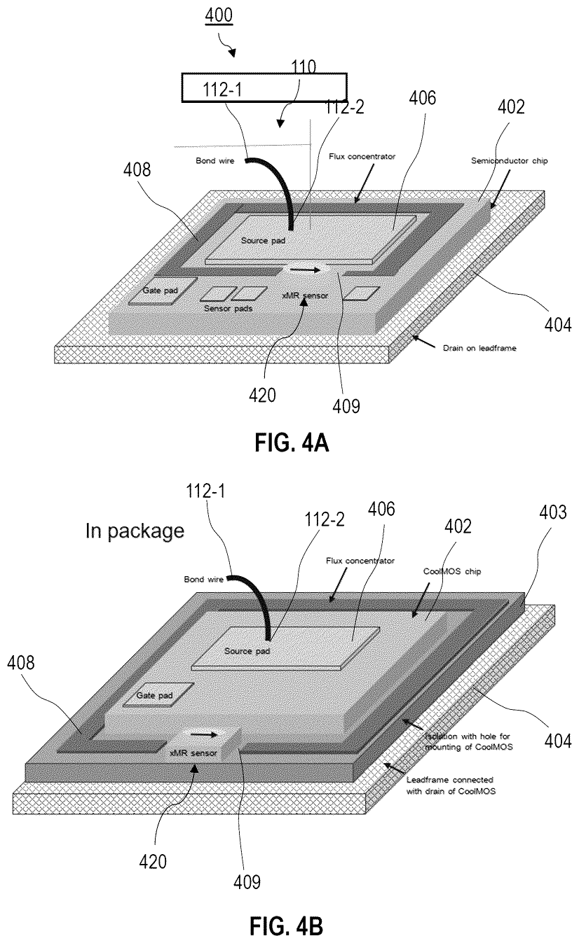

FIG. 4A schematically shows a device 400 for measuring current comprising a substrate 402 which spans a plane (e.g., the x-y plane). The substrate 402 can be formed, for example, by a semiconductor chip. Other examples of the substrate 402 are a semiconductor package, an insulation layer, or a printed circuit board (PCB). The substrate 402 can comprise a vertical power MOSFET extending in the z direction within the substrate 402. In the implementation shown, the substrate 402 has again been put onto a leadframe 404. The arrangement of FIG. 4A may optionally be surrounded by a housing (not shown).

The device 400 comprises a current conductor 110 having a first conductor section 112-1 extending outside of the substrate (semiconductor chip) 402. The first conductor section 112-1 can be formed, for example, by a bond wire. A bond wire is a fine wire used in microelectronics to make electrical connections between a semiconductor chip (die) and terminals of a housing or conductor tracks of a printed circuit board (PCB).

The current conductor 110 also has a second conductor section 112-2 adjoining the first conductor section 112-1, which extends outside of the substrate (semiconductor chip) 402, and extending within the substrate (semiconductor chip) 402 and perpendicular to the substrate plane (e.g., in the z direction). The second conductor section 112-2 may, for example, extend through a vertical power component (e.g., vertical MOSFET) which may be embedded within the substrate 402 (e.g., semiconductor chip, semiconductor package, PCB, etc.). For example, the second conductor section 112-2 can comprise a source-drain channel of the vertical MOSFET.

In the implementation shown, the first conductor section 112-1 extends to a first terminal 406 of the vertical power component. The first terminal 406 can be a source terminal (here: source pad) of a vertical MOSFET. The second conductor section 112-1 extends perpendicular to the substrate plane (e.g., in the z direction) between the first terminal 406 and a second terminal (not shown) of the vertical power component. The second terminal can be a drain terminal (here: drain pad) of a vertical MOSFET. The second terminal is formed on the opposite side of the substrate (semiconductor chip) 402 to the first terminal 406. Here too, the conductor sections 112-1, 112-2 are essentially L-shaped.

The device 400 also comprises at least one magnetic field sensor 420 arranged on the substrate 402 (chip surface) to measure a magnetic field caused by a current through the second conductor section 112-2 extending perpendicular to the substrate plane (e.g., in the z direction). According to some implementations, the magnetic field sensor 420 is configured to detect one or more magnetic field components parallel to the substrate plane (here: x-y plane). The magnetic field sensor 420 may thus be configured to detect in-plane magnetic field components in the x and/or y direction. For this purpose, the magnetic field sensor 420 can be in the form of an xMR sensor or in the form of a vertical Hall sensor.

In the implementation shown in FIG. 4A, the first terminal 406 or the second conductor section 112-2 extending perpendicular to the substrate plane (e.g., in the z direction) is surrounded annularly by a flux concentrator 408 arranged flat on the substrate 402. The magnetic field sensor 420 is arranged on the substrate 402 (chip surface) within a gap 409 in the annular flux concentrator 408. The flux concentrator 408 can thus also be situated in the substrate plane or parallel thereto. The flux concentrator 408 is a device or structure used to bundle and focus magnetic flux lines in a specific area (e.g., gap 409). It may contain ferromagnetic material (e.g., soft iron, nickel, cobalt, permalloy, etc.), which has a high magnetic permeability value.

FIG. 4B schematically shows another device 400 for measuring current comprising a substrate 403 which spans a plane (e.g., x-y plane). Here, the substrate 403 is formed by an insulation layer on which the semiconductor chip 402 comprising the vertical power component (e.g., vertical MOSFET) is arranged. In the implementation shown, the substrate (insulation layer) 403 has again been put onto the leadframe 404. The arrangement of FIG. 4B may optionally be surrounded by a housing (not shown). The substrate (insulation layer) 403 may have a hole/an inlet for contact-connecting the semiconductor chip 402 (or) MOSFET to the leadframe 404.

The insulation layer between the semiconductor chip 402 and the leadframe 404 that forms the substrate 403 prevents direct electrical contact between the semiconductor chip 402 and the leadframe 404, thereby allowing short circuits to be avoided. Possible materials for the electrical insulation layer 403 include polyimides, silicone, epoxy resins or ceramics. The electrical insulation layer 403 can be used to safely separate different circuit parts and thus ensure the functionality and reliability of the semiconductor chip 402.

The device 400 of FIG. 4B also comprises a current conductor 110 having a first conductor section 112-1 extending outside of the semiconductor chip 402. The first conductor section 112-1 can be formed, for example, by a bond wire. The current conductor 110 has a second conductor section 112-2 adjoining the first conductor section 112-1, which extends outside of the semiconductor chip 402, and extending within the semiconductor chip 402 and perpendicular to the substrate plane (e.g., in the z direction). The second conductor section 112-2 may, for example, extend through a vertical power component (e.g., vertical MOSFET) which may be embedded within the semiconductor chip 402. For example, the second conductor section 112-2 can comprise a source-drain channel of a vertical MOSFET.

In the implementation shown, the first conductor section 112-1 extends to a first terminal 406 of the vertical power component. The first terminal 406 can be a source terminal (here: source pad) of a vertical MOSFET. The second conductor section 112-1 extends perpendicular to the substrate plane (e.g., in the z direction) between the first terminal 406 and a second terminal (not shown) of the vertical power component. The second terminal can be a drain terminal (here: drain pad) of a vertical MOSFET. The second terminal is formed on the opposite side of the semiconductor chip 402 to the first terminal 406.

The device 400 of FIG. 4B also comprises at least one magnetic field sensor 420 arranged on the substrate (insulation layer) 403 to measure a magnetic field caused by a current through the second conductor section 112-2, extending perpendicular to the substrate plane (e.g., in the z direction). According to some implementations, the magnetic field sensor 420 is configured to detect one or more magnetic field components parallel to the substrate plane (here: x-y plane). The magnetic field sensor 420 may thus be configured to detect magnetic field components in the x and/or y direction. For this purpose, the magnetic field sensor 420 can be in the form of an xMR sensor or in the form of a vertical Hall sensor.

In the implementation shown in FIG. 4B, the semiconductor chip 402 is surrounded annularly by a flux concentrator 408 arranged flat on the insulation layer 403. The magnetic field sensor 420 is arranged on the insulation layer 403 (substrate surface) within a gap 409 in the annular flux concentrator 408. The insulation layer 403 is arranged between the magnetic field sensor 420 and flux concentrator 408 and the leadframe 404.

The implementations shown in FIG. 4A and FIG. 4B do not require differential magnetic field sensors.

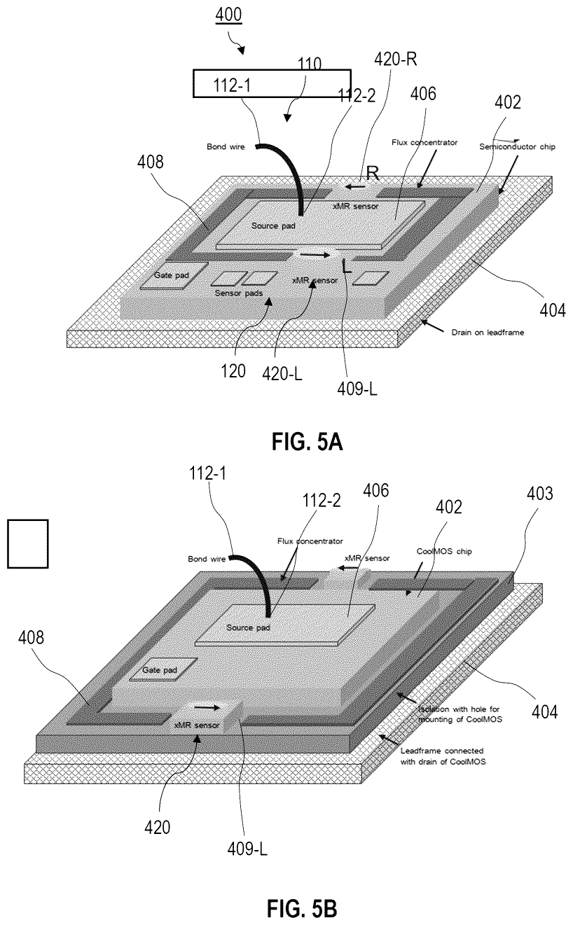

FIG. 5A schematically shows another device 400 for measuring current similar to FIG. 4A. The device 400 of FIG. 5A differs from that of FIG. 4A in that the annular flux concentrator 408 has gaps 409-L and 409-R on two opposite sides of the terminal (source pad) 406, in each of which gaps a magnetic field sensor 420-L or 420-R is arranged on the semiconductor chip 402. Reference magnetizations of the magnetic field sensors 420-L and 420-R can be opposite (e.g., +x for magnetic field sensor 420-L, −x for magnetic field sensor 420-R). This enables a differential measuring principle to be implemented.

FIG. 5B schematically shows a device 400 for measuring current similar to FIG. 4B. The device 400 of FIG. 5B differs from that of FIG. 4B in that the annular flux concentrator 408 has gaps 409-L and 409-R on two opposite sides of the semiconductor chip 402, in each of which gaps a magnetic field sensor 420-L or 420-R is arranged on the insulation layer 403. Reference magnetizations of the magnetic field sensors 420-L and 420-R can be opposite (e.g., +x for magnetic field sensor 420-L, −x for magnetic field sensor 420-R). This enables a differential measuring principle to be implemented.

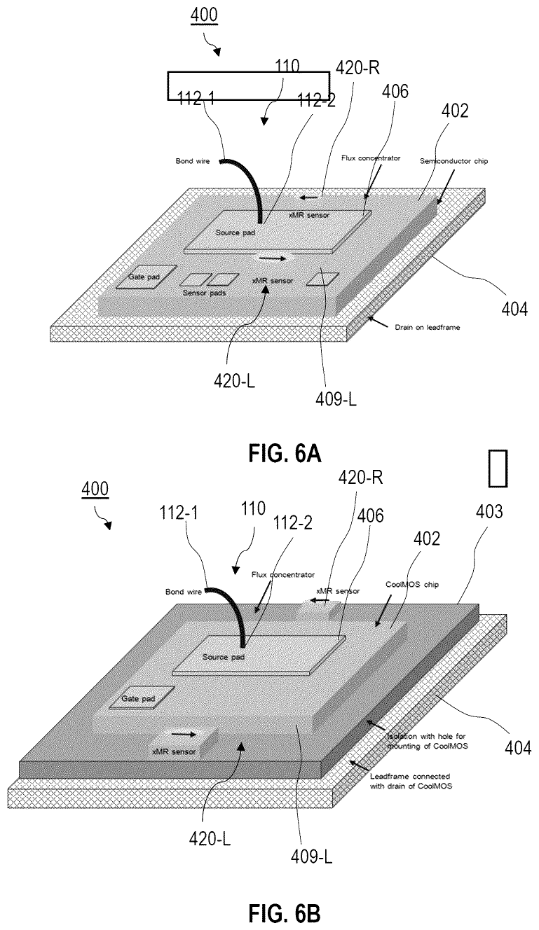

FIGS. 6A and 6B each show devices 400 for measuring current similar to FIGS. 5A and 5B, with the difference that the respective flux concentrators 408 have been omitted here.

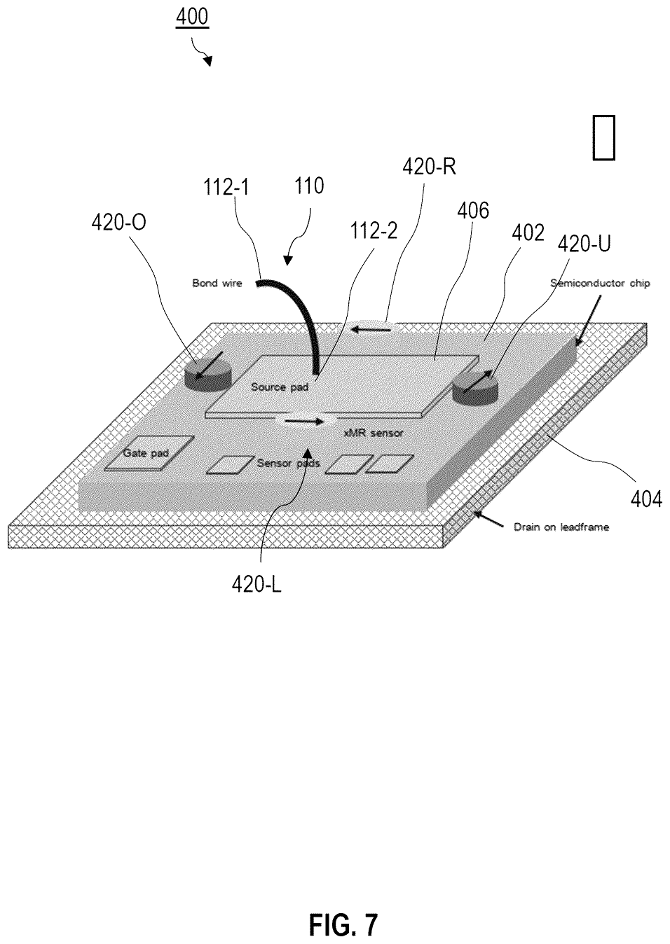

FIG. 7 shows another device 400 for measuring current similar to FIG. 6A, with the difference that two further magnetic field sensors 420-O and 420-U are used on opposite sides of the terminal (source pad) 406 here. While the magnetic field sensors 420-L and 420-R are sensitive in the x direction, the magnetic field sensors 420-O and 420-U are sensitive in the y direction.

The aspects and features described in connection with a particular one of the previous examples may also be combined with one or more of the other examples to replace an identical or similar feature of this other example or to introduce the feature additionally into the other example.

Furthermore, it goes without saying that the disclosure of multiple steps, processes, operations or functions disclosed in the description or claims should not be interpreted as necessarily being in the described order, unless this is explicitly stated in the individual case or is mandatory for technical reasons. Therefore, the previous description does not restrict the execution of multiple steps or functions to a specific order. Furthermore, in other examples, a single step, a single function, a single process or a single operation may include and/or be broken into multiple substeps, subfunctions, subprocesses or suboperations.

If some aspects have been described in the preceding sections in connection with an apparatus or system, these aspects should also be understood as a description of the corresponding method. In this case, for example, a block, an apparatus or a functional aspect of the apparatus or the system may correspond to a feature, such as a method step, of the corresponding method. Correspondingly, aspects described in connection with a method should also be understood as a description of a corresponding block, a corresponding element, a property or a functional feature of a corresponding apparatus or of a corresponding system.

The following claims are hereby incorporated into the detailed description, each claim being independent as a separate example. It should also be noted that—although a dependent claim in the claims refers to a particular combination with one or more other claims—other examples may also comprise a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

The following provides an overview of some Aspects of the present disclosure:
Aspect 1: A device for measuring current, comprising: a current conductor having a first conductor section extending in one plane, and having a second conductor section adjoining one end of the first conductor section and extending perpendicular to the plane; and a differential magnetic field sensor arranged parallel to the plane, having a first sensor element and a second sensor element, wherein the first sensor element is at a first distance from the end of the first conductor section and the second sensor element is at a second distance from the end of the first conductor section.
Aspect 2: The device as recited in Aspect 1, wherein the first sensor element is at the first distance in a direction of the first conductor section and the second sensor element is at the second distance in the direction of the first conductor section.
Aspect 3: The device as recited in any of Aspects 1-2, wherein the differential magnetic field sensor is arranged in a direction of the first conductor section after the end of the first conductor section.
Aspect 4: The device as recited in any of Aspects 1-3, wherein the first sensor element is at the first distance in the plane and perpendicular to the first conductor section and the second sensor element is at the second distance in the plane and perpendicular to the first conductor section.
Aspect 5: The device as recited in any of Aspects 1-4, wherein the differential magnetic field sensor is arranged outside of a corner between the first conductor section and the second conductor section of the current conductor.
Aspect 6: The device as recited in any of Aspects 1-5, wherein the differential magnetic field sensor is configured to detect one or more magnetic field components parallel to the plane.
Aspect 7: The device as recited in any of Aspects 1-6, wherein the differential magnetic field sensor comprises at least one bridge circuit consisting of magnetoresistive elements or vertical Hall sensors and wherein the first and second sensor elements are assigned to different bridge branches or bridge circuits.
Aspect 8: The device as recited in any of Aspects 1-7, wherein the second conductor section of the current conductor extends within a semiconductor chip.
Aspect 9: The device as recited in Aspect 8, wherein the semiconductor chip comprises a vertical power Metal-Oxide-Semiconductor Field-Effect Transistor (MOSFET) which comprises the second conductor section.
Aspect 10: The device as recited in any of Aspects 1-9, wherein the first conductor section extends toward a first terminal of a vertical power component and the second conductor section extends between the first terminal and a second terminal of the vertical power component.
Aspect 11: The device as recited in Aspect 10, wherein the first terminal of the vertical power component is arranged on a first surface of a semiconductor chip and the second terminal of the vertical power component is arranged on an opposite second surface of the semiconductor chip.
Aspect 12: A device for measuring current, comprising: a substrate which spans a plane; a current conductor having a first conductor section extending outside of the substrate and parallel to the plane, and having a second conductor section adjoining the first conductor section and extending within the substrate and perpendicular to the plane; and at least one magnetic field sensor arranged on the substrate to measure a magnetic field caused by a current through the second conductor section.
Aspect 13: The device as recited in Aspect 12, wherein the first conductor section extends toward a first terminal of a vertical power component and the second conductor section extends between the first terminal and a second terminal of the vertical power component.
Aspect 14: The device as recited in any of Aspects 12-13, wherein the magnetic field sensor comprises a differential magnetic field sensor having a first sensor element and a second sensor element on opposite sides of the second conductor section in the plane.
Aspect 15: The device as recited in any of Aspects 12-14, wherein the second conductor section is surrounded by a flux concentrator arranged flat on the substrate, and wherein the at least one magnetic field sensor is arranged within at least one gap in the flux concentrator.
Aspect 16: The device as recited in any of Aspects 12-15, wherein the substrate comprises a semiconductor chip having a vertical power component or an insulation layer between the semiconductor chip and a leadframe.
Aspect 17: The device as recited in Aspect 16, wherein the semiconductor chip comprises a vertical power Metal-Oxide-Semiconductor Field-Effect Transistor (MOSFET) which forms the second conductor section.
Aspect 18: The device as recited in any of Aspects 12-17, wherein the at least one magnetic field sensor is configured to detect one or more magnetic field components parallel to the plane.
Aspect 19: A system configured to perform one or more operations recited in one or more of Aspects 1-18.
Aspect 20: An apparatus comprising means for performing one or more operations recited in one or more of Aspects 1-18.

1. A device for measuring current, comprising:
a current conductor having a first conductor section extending in one plane, and having a second conductor section adjoining one end of the first conductor section and extending perpendicular to the plane; and
a differential magnetic field sensor arranged parallel to the plane, having a first sensor element and a second sensor element,
wherein the first sensor element is at a first distance from the end of the first conductor section and the second sensor element is at a second distance from the end of the first conductor section.

2. The device as claimed in claim 1, wherein the first sensor element is at the first distance in a direction of the first conductor section and the second sensor element is at the second distance in the direction of the first conductor section.

3. The device as claimed in claim 1, wherein the differential magnetic field sensor is arranged in a direction of the first conductor section after the end of the first conductor section.

4. The device as claimed in claim 1, wherein the first sensor element is at the first distance in the plane and perpendicular to the first conductor section and the second sensor element is at the second distance in the plane and perpendicular to the first conductor section.

5. The device as claimed in claim 1, wherein the differential magnetic field sensor is arranged outside of a corner between the first conductor section and the second conductor section of the current conductor.

6. The device as claimed in claim 1, wherein the differential magnetic field sensor is configured to detect one or more magnetic field components parallel to the plane.

7. The device as claimed in claim 1,
wherein the differential magnetic field sensor comprises at least one bridge circuit consisting of magnetoresistive elements or vertical Hall sensors and
wherein the first and second sensor elements are assigned to different bridge branches or bridge circuits.

8. The device as claimed in claim 1, wherein the second conductor section of the current conductor extends within a semiconductor chip.

9. The device as claimed in claim 8, wherein the semiconductor chip comprises a vertical power Metal-Oxide-Semiconductor Field-Effect Transistor (MOSFET) which comprises the second conductor section.

10. The device as claimed in claim 1, wherein the first conductor section extends toward a first terminal of a vertical power component and the second conductor section extends between the first terminal and a second terminal of the vertical power component.

11. The device as claimed in claim 10, wherein the first terminal of the vertical power component is arranged on a first surface of a semiconductor chip and the second terminal of the vertical power component is arranged on an opposite second surface of the semiconductor chip.

12. A device for measuring current, comprising:
a substrate which spans a plane;
a current conductor having a first conductor section extending outside of the substrate and parallel to the plane, and having a second conductor section adjoining the first conductor section and extending within the substrate and perpendicular to the plane; and
at least one magnetic field sensor arranged on the substrate to measure a magnetic field caused by a current through the second conductor section.

13. The device as claimed in claim 12, wherein the first conductor section extends toward a first terminal of a vertical power component and the second conductor section extends between the first terminal and a second terminal of the vertical power component.

14. The device as claimed in claim 12, wherein the magnetic field sensor comprises a differential magnetic field sensor having a first sensor element and a second sensor element on opposite sides of the second conductor section in the plane.

15. The device as claimed in claim 12,
wherein the second conductor section is surrounded by a flux concentrator arranged flat on the substrate, and
wherein the at least one magnetic field sensor is arranged within at least one gap in the flux concentrator.

16. The device as claimed in claim 12, wherein the substrate comprises a semiconductor chip having a vertical power component or an insulation layer between the semiconductor chip and a leadframe.

17. The device as claimed in claim 16, wherein the semiconductor chip comprises a vertical power Metal-Oxide-Semiconductor Field-Effect Transistor (MOSFET) which forms the second conductor section.

18. The device as claimed in claim 12, wherein the at least one magnetic field sensor is configured to detect one or more magnetic field components parallel to the plane.
